(19) United States
(12) Patent Application Publication
(10) Pub. No.: US 2023/0213557 A1
(43) Pub. Date: Jul. 6, 2023

(54) Test Shunt Clamp Device

(71) Applicant: Wilburn Doyle King, Panama City, FL (US)

(72) Inventor: Wilburn Doyle King, Panama City, FL (US)

(21) Appl. No.: 18/150,307

(22) Filed: Jan. 5, 2023

Related U.S. Application Data
(60) Provisional application No. 63/296,568, filed on Jan. 5, 2022.

(51) Int. Cl. G01R 15/14; B61L 1/18

(52) U.S. Cl. CPC G01R 15/146; B61L 1/181

(57) ABSTRACT

The present invention relates to a test shunt clamp device for testing railroad tracks by creating either a hard-wired effect or an impedance. The device has at least two clamps that can be attached to a rail track of a railroad track. Once attached, a toggle switch can be placed in the “HW” or “0.06” position such that the switchable choice between hard-wire and a resistor (that the first and second wires are connected to) delivers a hard-wired effect or a 0.06 ohm impedance to each rail track via a first pointed member of the first clamp attached to the first wire and a second pointed member of the second clamp attached to the second wire.

### CROSS-REFERENCE TO RELATED APPLICATION

The present application claims priority to, and the benefit of, U.S. Provisional Application No. 63/296,568, which was filed on Jan. 5, 2022, and is incorporated herein by reference in its entirety.

### FIELD OF THE INVENTION

The present invention relates generally to the field of test shunts. More specifically, the present invention relates to a test shunt clamp device. The device has at least two clamps that can be attached to each rail track of a railroad track. Once attached to each track rail, the two track rails are hard-wired to each other. The toggle switch can be placed in the “0.06” position such that a resistor (that the first and second wires are connected to) delivers a 0.06 ohm impedance between the rail track via a first pointed member of the first clamp attached to the first wire and a second pointed member of the second clamp attached to the second wire. Accordingly, the present disclosure makes specific reference thereto. Nonetheless, it is to be appreciated that aspects of the present invention are also equally applicable to other like applications, devices, and methods of manufacture.

### BACKGROUND

Test Shunts are used by railroad signalmen to test the function and readiness of train detection gear via the attachment of test pins to each of two railroad rails. Currently, existing railroad signalmen attach test pins of their test shunts with C-Clamps or other similar devices to railroad rails by actually screwing the closure to the track rail and tightening it to create an electrical connection between the C-Clamp and the rail. However, said devices require time and effort while turning and adjusting the closing screw to attach the device to the track rail. The device must then also be removed from the rail once testing is complete by the same action of unscrewing the C-Clamp. Other testing options do exist but require additional persons to complete and have their own set of unique disadvantages.

Therefore, there exists a long-felt need in the art for a device that can be used instead of a C-Clamp or other similar device to be used on a test shunt to secure test pins onto a railroad track to test track drivers. Further, there exists a long-felt need in the art for a device that can be used instead of a C-Clamp or other similar device to be used on a test shunt to secure test pins onto a railroad track to test track drivers that is not overly time-consuming. Finally, there exists a long-felt need in the art for a device that can be used instead of a C-Clamp or other similar device to be used on a test shunt to secure test pins onto a railroad track to test track drivers that only requires a singular user.

The subject matter disclosed and claimed herein, in one embodiment thereof, comprises a test shunt clamp device. The device is comprised of a housing with at least one toggle switch, at least one resistor, a first wire attached to a first clamp with at least one pointed member, and a second wire attached to a second clamp with at least one pointed member. Each clamp can be attached to a rail track of a railroad track. Once attached, the toggle switch can be placed in either of two positions such that, in position 1 (identified by “HW” on one side of the toggle switch) the two track rails are “hardwired” to each other and in position 2 (identified by “0.06” on the other side of the toggle switch) such that the resistor (that the first and second wires are connected to) delivers a 0.06 ohm impedance to each rail track via the first pointed member of the first clamp attached to the first wire and the second pointed member of the second clamp attached to the second wire.

In this manner, the test shunt clamp device of the present invention accomplishes all the foregoing objectives and provides a device that can be used instead of a C-Clamp or other similar device to be used on a test shunt to secure test pins onto a railroad track to test track drivers. Further, the device does so in an efficient manner. Finally, the device only requires a singular user.

### SUMMARY

The following presents a simplified summary to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises a test shunt clamp device. The device is comprised of a housing with at least one toggle switch, at least one resistor, a first wire attached to a first clamp with at least one pointed member, and a second wire attached to a second clamp with at least one pointed member.

The first wire and the second wire each enter the housing via at least one insulated grommet opening and connect to a first terminal and a second terminal within the housing. The first wire and second wire then connect to at least one resistor and the toggle switch via a series of connector wiring such that the resistor, the toggle switch, the first wire, the second wire, and the connector wiring are in wired, electrical communication. The wiring of the first wire, second wire, and connector wiring may be any type of insulated wire known in the art that can carry an electrical charge. The resistor is preferably a 0.06 ohm resistor but may differ in various embodiments.

The first wire and second wire are each comprised of at least one clamp that is preferably a C-clamp style locking clamp that can easily attach to (and remain secured to) a railroad track. Each clamp is comprised of a first jaw and a second jaw attached at a hinge point that allows the clamp to open/close. The clamp may be comprised of at least one locking mechanism that allows the jaws to be secured at any position. Each jaw is comprised of at least one pointed member that contacts the rail during use of the device. At least one wire attachment member attaches the first wire to one of the pointed members such that the electrical current can flow through the wire to and from the resistor and the track through the member.

During use, each clamp is attached to each rail of a railroad track such that the electrical current of each rail travels through the first wire and second wire. When a signalman is working on and testing railroad track signals, they may oftentimes need to create an exact impedance of 0.06 ohm. Pressing the toggle switch to an “0.06 position” allows the resistor to create said 0.06 ohm impedance by interrupting the primary flow of the electrical current from each rail. This is done to mimic the conditions present when a locomotive or rail car creates a short circuit. Pressing the switch to the “hard wired” position stops the impedance but maintains a dead short between the rails

The device is also comprised of a method of using the device. First, the first clamp is opened, placed around a first rail track, closed, and secured in said position by locking the single-action locking mechanism. Then, the second clamp is opened, placed around a second rail track, closed, and secured in said position by locking the single-action locking mechanism. Next, the switch can be pushed to either the “HW” or the “0.06 ” position such that the two tracks will be either “Hard-wired” to each other or connected to each other with 0.06 ohm resistance through the resistor to allow the railroad signalman to test and perform any other necessary operations to the tracks as needed by mimicking the condition of a (“Hard-wired” or “0.06 ” ohm) short circuit. Next, the locking mechanism of each clamp can be unlocked with a single action to remove each clamp from each rail.

Accordingly, the test shunt clamp device of the present invention by accomplishing single-action attachment/detachment and selectable (“HW”; “0.06 ” ohm) is particularly advantageous as it provides a device that can be used instead of a time-consuming C-Clamp and the labor-intensive two person devices to test track drivers. In this manner, the test shunt clamp device overcomes the limitations of existing methods of testing railroad track drivers known in the art.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective view of one potential embodiment of a test shunt clamp device of the present invention in accordance with the disclosed architecture;

FIG. 2 illustrates a top perspective view of a housing and lid of one potential embodiment of a test shunt clamp device of the present invention in accordance with the disclosed architecture;

FIG. 3 illustrates a top perspective view of an interior space of a housing of one potential embodiment of a test shunt clamp device of the present invention in accordance with the disclosed architecture;

FIG. 4 illustrates a perspective view of a clamp of one potential embodiment of a test shunt clamp device of the present invention in accordance with the disclosed architecture;

FIG. 5 illustrates a perspective view of a jaw of a clamp of one potential embodiment of a test shunt clamp device of the present invention in accordance with the disclosed architecture;

FIG. 6 illustrates a perspective view of a clamp of one potential embodiment of a test shunt clamp device of the present invention in accordance with the disclosed architecture;

FIG. 7 illustrates a perspective view of a carrying case of one potential embodiment of a test shunt clamp device of the present invention in accordance with the disclosed architecture; and

FIG. 8 illustrates a flowchart of a method of using one potential embodiment of a test shunt clamp device of the present invention in accordance with the disclosed architecture.

### DETAILED DESCRIPTION

The innovation is now described with reference to the drawings, wherein like reference numerals are used to refer to like elements throughout. In the following description, for purposes of explanation, numerous specific details are set forth to provide a thorough understanding thereof. It may be evident, however, that the innovation can be practiced without these specific details. In other instances, well-known structures and devices are shown in block diagram form to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there exists a long-felt need in the art for a device that can be used instead of a C-Clamp or other similar device to be used on a test shunt to secure test pins onto a railroad track to test track drivers. Further, there exists a long-felt need in the art for a device that can be used instead of a C-Clamp or other similar device to be used on a test shunt to secure test pins onto a railroad track to test track drivers that is not overly time-consuming. Finally, there exists a long-felt need in the art for a device that can be used instead of a C-Clamp or other similar device to be used on a test shunt to secure test pins onto a railroad track to test track drivers that only requires a singular user.

The present invention, in one exemplary embodiment, is comprised of a test shunt clamp device. The device is comprised of a housing with at least one toggle switch, at least one resistor, a first wire attached to a first clamp with at least one pointed member, and a second wire attached to a second clamp with at least one pointed member. The first wire and the second wire each enter the housing via at least one insulated grommet opening and connect to a first terminal and a second terminal within the housing. The first wire and second wire then connect to at least one resistor (preferably a 0.06 ohm resistor) and the toggle switch via a series of connector wiring such that the resistor, the toggle switch, the first wire, the second wire, and the connector wiring are in wired, electrical communication. The wiring of the first wire, second wire, and connector wiring may be any type of insulated wire known in the art that can carry an electrical charge.

The first wire and second wire are each comprised of at least one clamp that is preferably a C-clamp style locking clamp that can easily attach to (and remain secured to) a railroad track. Each clamp is comprised of a first jaw and a second jaw attached at a hinge point that allows the clamp to open/close. The clamp may be comprised of at least one locking mechanism that allows the jaws to be secured at any position. Each jaw is comprised of at least one pointed member. The member contacts the rail during use of the device. At least one wire attachment member attaches the first wire to one of the pointed members such that the electrical current can flow through the wire to and from the resistor and the track through the member.

During use, each clamp is attached each to one of the rails of a railroad track such that the electrical current of each rail travels through the first wire and second wire without any impedance. A signalman can then use the device to create an exact impedance of 0.06 ohm. This is done by pressing the toggle switch to an “0.06 ” which allows the resistor to create said 0.06 ohm impedance by interrupting the primary flow of the electrical current from each rail. As a result, the device mimics the conditions present when a locomotive or rail car creates a short circuit. Pressing the switch to the “HW” position stops the impedance and returns the flow of power to the clamps without any impedance.

The device is also comprised of a method of using the device. First, the first clamp is opened, placed around a first rail track, closed, and secured in said position by locking the single action locking mechanism. Then, the second clamp is opened, placed around a first rail track, closed, and secured in said position by locking the single action locking mechanism. Next, the switch can be pushed to the “0.06 ” position such that the resistor creates a 0.06 ohm impedance to allow the railroad signalman to test the tracks as needed by mimicking the condition of a short circuit. Once testing has been completed, the switch can be toggled to the “hard wired” position to shut off the resistor. Next, the locking mechanism of each clamp can be unlocked by single action and each clamp can be removed from each rail.

Accordingly, the test shunt clamp device of the present invention is particularly advantageous as it provides a device that can be used instead of a C-Clamp to test track drivers. Further, the device does so in an efficient manner while only requiring a singular user. In this manner, the test shunt clamp device overcomes the limitations of existing methods of testing railroad track drivers known in the art.

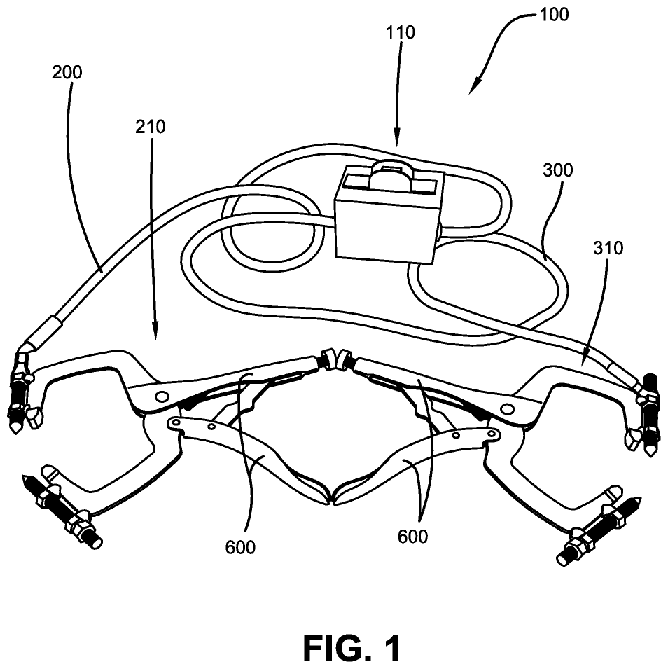

Referring initially to the drawings, FIG. 1 illustrates a perspective view of one potential embodiment of a test shunt clamp device 100 of the present invention in accordance with the disclosed architecture. The device 100 is comprised of a housing 110 with at least one toggle switch 114, at least one resistor 154, a first wire 200 attached to a first clamp 210 with at least one pointed member 232, and a second wire 300 attached to a first clamp 310 with at least one pointed member 332.

The housing 110 may be made from any material known in the art such as but not limited to wood, metal, plastic, etc. The material of the housing 110 is preferably waterproof. In one embodiment, the material of the housing 110 may be made from a non-conductive material that prevents a user from being shocked by the device 100. The housing 110 is preferably square or rectangular in shape, but may be any shape known in the art that allows components of the device 100 to be housed into the interior space 120, such as, but not limited to, at least one insulator 130 of any electrical insulating material known in the art.

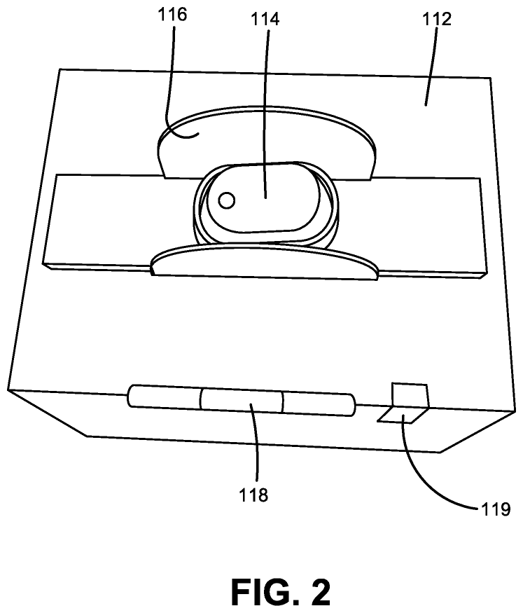

The lid 112 of the housing 110 may have at least one hinge 118 (or a fold) that allows the lid 112 to open/close to access the internal components of the device 100 for maintenance purposes. The hinge 118 may be any type known in the art. The lid 112 is comprised of at least one toggle switch 114 protected by at least one switch guard 116 that prevents the switch 114 from being accidentally engaged, as best seen in FIG. 2. In one embodiment, the lid 112 may be secured to the housing 110 via at least one locking mechanism 119 such as but not limited to a lock, a clamp, a latch, a fastener, etc. This ensures the lid 112 stays closed during use, protecting the internal components of the device 100.

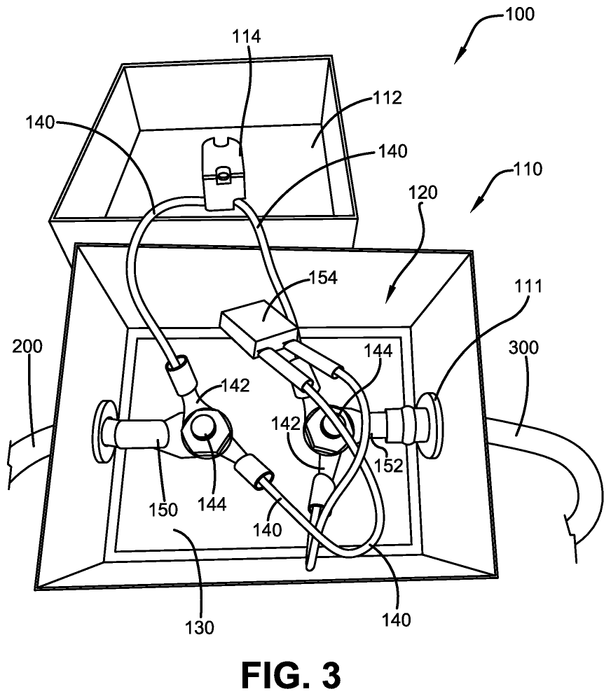

FIG. 3 illustrates a top perspective view of an interior space 120 of a housing 110 of one potential embodiment of a test shunt clamp device 100 of the present invention in accordance with the disclosed architecture. A first wire 200 and a second wire 300 each enter the housing 110 via at least one insulated grommet opening 111 and connect to a first terminal 150 and a second terminal 152. The first wire 200 and second wire 300 then connect to at least one resistor 154 within the housing 110 and the toggle switch 114 via a series of connector wiring 140 such that the resistor 154, the toggle switch 114, the first wire 200, the second wire 300, and the connector wiring 140 are in wired, electrical communication. The terminals 150,152 and connector wiring 140 are each comprised of an eyelet 142 that allows the first wire 200 to be secured to the resistor 154 and toggle switch 114 via the use of self-insulated fasteners 144 (of any type known in the art) through each eyelet 142. In the preferred embodiment, the fasteners 144 are a self-insulated bolt and nut assembly.

The wiring of the first wire 200, second wire 300, and connector wiring 140 may be any type of insulated wire known in the art that can carry an electrical charge. The first wire 200, second wire 300, and connector wiring 140 are preferably made from a coated copper wire. The resistor 154 is preferably a 0.06 ohm resistor but may differ in various embodiments.

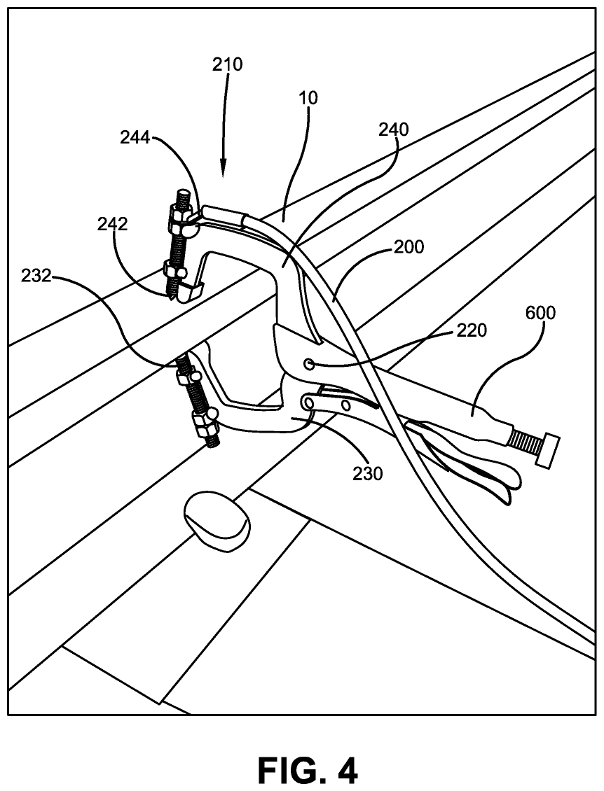

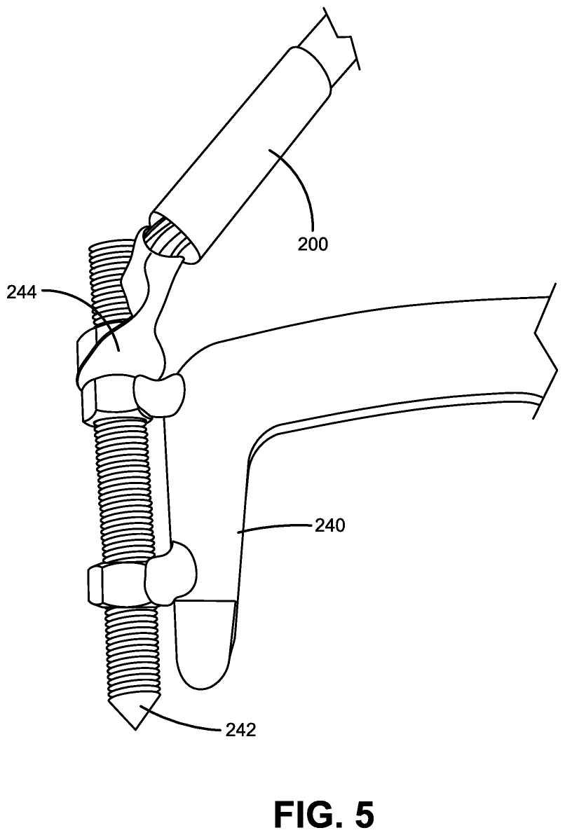

The first wire 200 is comprised of at least one first clamp 210, as seen in FIG. 4. The first clamp 210 is preferably a C-clamp style locking clamp, but may be any similar type of locking assembly that can easily attach to (and remain secured to) a railroad track 10. The clamp 210 is comprised of a first jaw 230 and a second jaw 240 attached at a hinge point 220 that allows the clamp 210 to open/close. The clamp 210 may be comprised of at least one locking mechanism 600, such as, but not limited to, a threaded locking mechanism, that allows the jaws 230,240 to be secured at any position. Each jaw 230, 240 is comprised of at least one pointed member 232,242 that contacts the rail 10 during use of the device 100, as seen in FIG. 5. At least one wire attachment member 244 attaches the first wire 200 to one of the pointed members 232,242 such that the electrical current can flow through the wire 200 to and from the resistor 154 and the track 10 through the members 232,242. In the preferred embodiment, the pointed members 232,242 and attachment member 244 have reciprocating threads such that the member 244 can be easily attached and secured to each member 232,242.

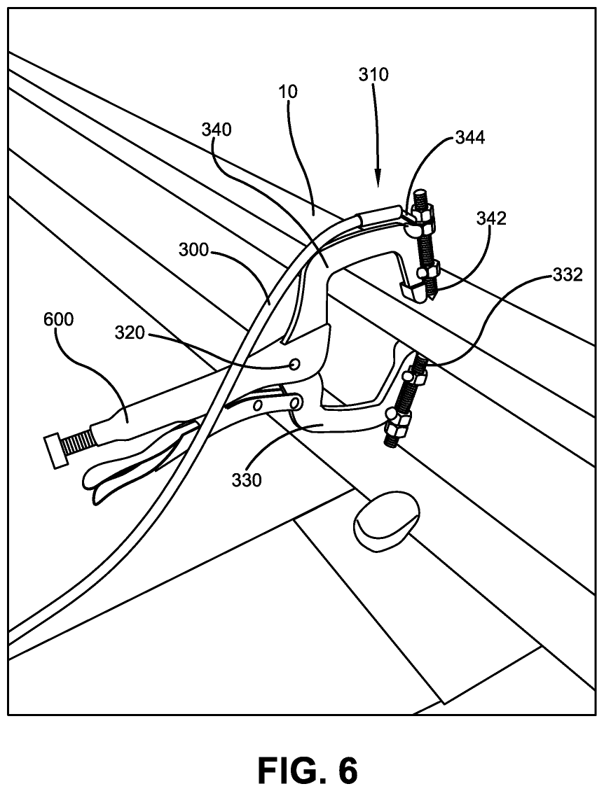

The second wire 300 is comprised of at least one first clamp 310, as seen in FIG. 6. The first clamp 310 is preferably a C-clamp style locking clamp, but may be any similar type of locking assembly that can easily attach to (and remain secured to) a railroad track 10. The clamp 310 is comprised of a first jaw 330 and a second jaw 340 attached at a hinge point 330 that allows the clamp 310 to open/close. The clamp 310 may be comprised of at least one locking mechanism 600, such as, but not limited to, a threaded locking mechanism, that allows the jaws 330,340 to be secured at any position. Each jaw 330,340 is comprised of at least one of the pointed members 332,342 that contacts the rail 10 during use of the device 100. At least one wire attachment member 344 attaches the first wire 300 to one of the pointed members 332,342 such that the electrical current can flow through the wire 300 to and from the resistor 154 and the track 10 through the members 332,342. In the preferred embodiment, the pointed members 332,342 and attachment member 344 have reciprocating threads such that the member 344 can be easily attached and secured to each of the members 332,342.

During use, each clamp 210,310 is attached to each rail 10 of a railroad track such that the electrical current of each rail 10 travels through the first wire 200 and the second wire 300. When a signalman is working on and testing railroad track signals, they may oftentimes need to create an exact impedance of 0.06 ohm. Pressing the switch 114 to an “0.06 ” allows the resistor 154 to create said 0.06 ohm impedance by interrupting the primary flow of the electrical current from each rail 10. This is done to mimic the conditions present when a locomotive or rail car creates a short circuit. Pressing the switch 114 to the “HW” position stops the impedance and returns the flow of power to the clamps without and impedance.

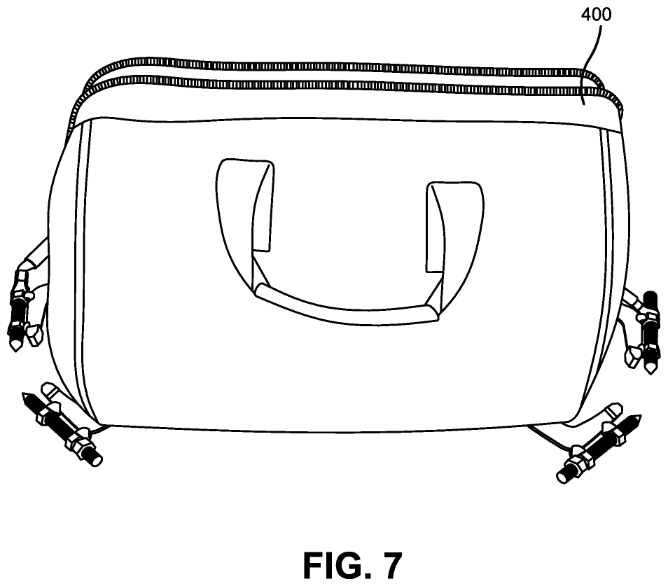

The device 100 can be transported in at least one carrying case 400, as seen in FIG. 7. The case 400 may be made from any material known in the art. The case 400 may be any style such as, but not limited to, a bag, a backpack, a briefcase, a soft case, a shoulder bag, a handbag, etc.

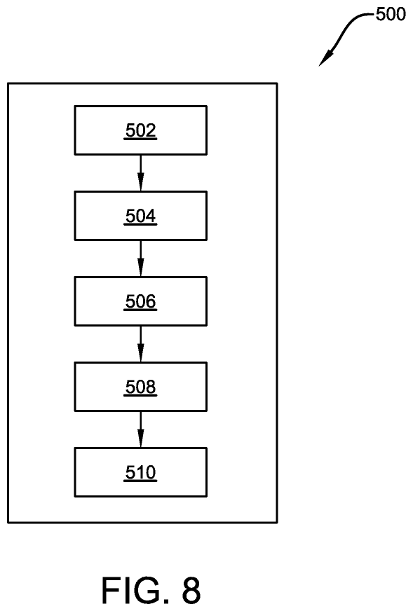

FIG. 8 illustrates a flowchart of a method of using 500 one potential embodiment of a test shunt clamp device 100 of the present invention in accordance with the disclosed architecture. The device 100 is also comprised of a method of using the device 500. First, the first clamp 210 is opened, placed around a first rail track 10, closed, and secured in said position by locking the locking mechanism 600 [Step 502]. Then, the second clamp 310 is opened, placed around a first rail track 10, closed, and secured in said position by locking the locking mechanism 600 [Step 504]. Next, the switch 114 is pushed to the “on” position such that the resistor 154 creates a 0.06 ohm impedance [Step 506]. This allows the railroad signalman to test the tracks 10 as needed by mimicking the condition of a short circuit. Once testing has been completed, the switch 114 can be toggled to the “off” position to shut off the resistor 154 [Step 508]. Next, the locking mechanism 600 of each clamp 210,310 can be unlocked and each clamp 210,310 can be removed from each rail 10 [Step 510].

Certain terms are used throughout the following description and claims to refer to particular features or components. As one skilled in the art will appreciate, different persons may refer to the same feature or component by different names. This document does not intend to distinguish between components or features that differ in name but not structure or function. As used herein “test shunt clamp device” and “device” are interchangeable and refer to the test shunt clamp device 100 of the present invention.

Notwithstanding the foregoing, the test shunt clamp device 100 of the present invention and its various components can be of any suitable size and configuration as is known in the art without affecting the overall concept of the invention, provided that they accomplish the above-stated objectives. One of ordinary skill in the art will appreciate that the size, configuration, and material of the test shunt clamp device 100 as shown in the FIGS. are for illustrative purposes only, and that many other sizes and shapes of the test shunt clamp device 100 are well within the scope of the present disclosure. Although the dimensions of the test shunt clamp device 100 are important design parameters for user convenience, the test shunt clamp device 100 may be of any size, shape, and/or configuration that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A test shunt clamp device comprising:
a housing;
a resistor;
a toggle switch;
a first wire;
a second wire;
an insulator material;
a first clamp comprised of a first pointed member and a first wire attachment member; and
a second clamp comprised of a second pointed member and a second wire attachment member.

2. The test shunt clamp device of claim 1, wherein the first clamp is comprised of a first locking mechanism.

3. The test shunt clamp device of claim 1, wherein the second clamp is comprised of a second locking mechanism.

4. The test shunt clamp device of claim 1, wherein a first terminal of the first wire attaches to a first eyelet of a first connecting wire and a second eyelet of a second connecting wire.

5. The test shunt clamp device of claim 4, wherein the first terminal attaches to the first eyelet and the second eyelet via a first self-insulated fastener.

6. The test shunt clamp device of claim 4, wherein the first connecting wire attaches to the toggle switch.

7. The test shunt clamp device of claim 4, wherein the second connecting wire attaches to the resistor.

8. The test shunt clamp device of claim 1, wherein a second terminal of the second wire attaches to a third eyelet of a third connecting wire and a fourth eyelet of a second connecting wire.

9. The test shunt clamp device of claim 8, wherein the second terminal attaches to the third eyelet and the fourth eyelet via a second self-insulated fastener.

10. The test shunt clamp device of claim 8, wherein the third connecting wire attaches to the toggle switch.

11. The test shunt clamp device of claim 8, wherein the fourth connecting wire attaches to the resistor.

12. The test shunt clamp device of claim 1, wherein the resistor is comprised of a 0.06 ohm resistor.

13. A test shunt clamp device comprising:
a housing comprised of a lid and a locking mechanism;
a resistor;
a toggle switch that activates the resistor;
a first wire;
a second wire;
an insulator material;
a first clamp comprised of a first pointed member and a first wire attachment member in wired electrical wired communication with the first wire;
a second clamp comprised of a second pointed member and a second wire attachment member in wired electrical wired communication with the second wire; and
a carrying case.

14. The test shunt clamp device of claim 13, wherein the first clamp is comprised of a first jaw and a second jaw that attach at a first hinge point.

15. The test shunt clamp device of claim 13, wherein the second clamp is comprised of a second jaw and a third jaw that attach at a second hinge point.

16. The test shunt clamp device of claim 13, wherein the housing is comprised of a first insulated grommet and a second insulated grommet.

17. The test shunt clamp device of claim 13, wherein the first wire and the second wire are each comprised of a coated copper wire.

18. The test shunt clamp device of claim 13 further comprised of a switch guard.

19. The test shunt clamp device of claim 18, wherein the toggle switch is positioned within the switch guard.

20. A method of using a test shunt clamp device, the method comprising the steps of:
opening a first clamp of a test shunt clamp device;
placing the first clamp around a first rail track;
closing the first clamp around the first rail track;
securing the first clamp to the first rail track via locking a first locking mechanism of the first clamp;
opening a second clamp of a test shunt clamp device;
placing the second clamp around a second rail track;
closing the second clamp around the second rail track;
securing the second clamp to the second rail track via locking a second locking mechanism of the second clamp; and
toggling a toggle switch of the test shunt clamp device to a 0.06 position such that a resistor of the test shunt clamp device creates a 0.06 ohm impedance that travels to the first rail track and the second rail track via the test shunt clamp device.
